(19) United States
(12) Patent Application Publication
(10) Pub. No.: US 2007/0047252 A1
(43) Pub. Date: Mar. 1, 2007

(54) Light distribution and control unit

(76) Inventors: Shawn D. Brune, Olathe, KS (US); Michael J. Slavik, Parkville, MO (US)

Correspondence Address: CHASE LAW FIRM L.C, 4400 COLLEGE BOULEVARD, SUITE 130, OVERLAND PARK, KS, 66211, US

(21) Appl. No.: 11/512,842

(22) Filed: Aug. 30, 2006

Related U.S. Application Data
(60) Provisional application No. 60/712,570, filed on Aug. 30, 2005.

(51) Int. Cl. H01L 33/00

(52) U.S. Cl. 362/555

(57) ABSTRACT

A light distribution and control unit is provided which includes an array of light emitting diodes controlled by a microprocessor and a plurality of optical fibers. The light emitted from the array is injected into one end of the optical fibers and emitted from the other ends. The emitter ends are distributed through the interior of a limousine or hot tub to provide accent lighting. Different light patterns may be produced by the microprocessor.

### CROSS REFERENCE TO RELATED APPLICATION

This application claims the benefit of a prior filed, co-pending application Ser. No. 60/712,570, filed Aug. 30, 2005, entitled LIGHT DISTRIBUTION AND CONTROL UNIT.

The present invention relates to lighting units and, more particularly, to a light distribution and control unit utilizing fiber optics to distribute light from an LED device source and a control unit to control the output of the LED device.

### BACKGROUND

Accent lighting for use in limousines and hot tubs, for example, is known in the art. In vehicles, a light box with two or more halogen lamps may be used as a source of accent lighting. The light from the halogen lamps is distributed within the vehicle using fiber optic strands terminated at the point of lighting. A color wheel, driven by a motor, may be included in the light box between the halogen lamps and the beginning of the fiber optic strands to vary the color of the light emanating from the fiber optic strand terminations. Halogen lamps are used because of their high light output.

One problem with this light box is the halogen lamps produce a tremendous amount of heat, consume a lot of electricity and require periodic replacement. The light wheel drive motor consumes electricity and is subject to normal mechanical wear. The prior art light box is typically bulky which limits mounting options. Additionally, the color pattern output from the color wheel is limited.

### SUMMARY

The present invention includes a compact LED module with multiple color LEDs and a controller to vary the color and pattern of the LED module output. Fiber optic strands receive light directly from the LED module for distribution according to the application and installation.

### BRIEF DESCRIPTION OF THE DRAWINGS

FIG. 1 is an illustration of the present invention installed in a limousine.

FIG. 2 is a diagrammatic illustration of the present invention.

FIG. 3 is an electrical schematic of the controller of the present invention.

FIG. 4 is an electrical schematic of the LED driver of the present invention.

### DETAILED DESCRIPTION

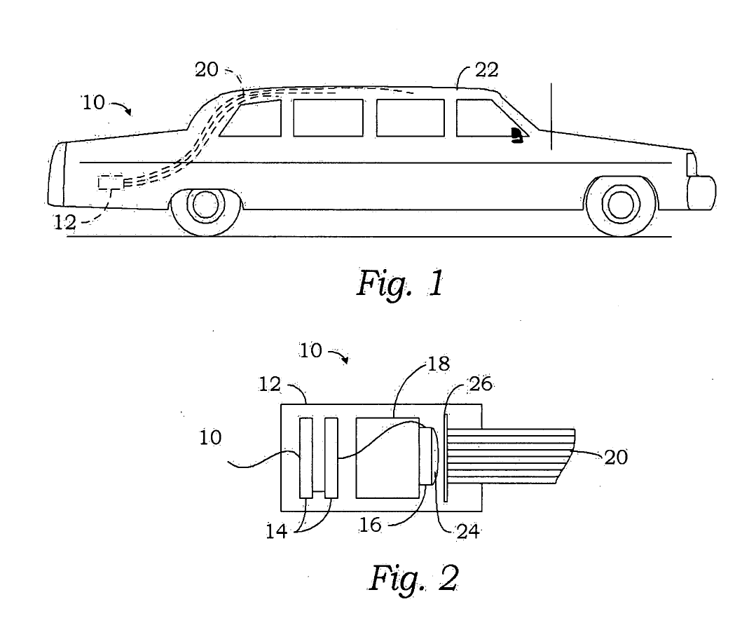

Referring to FIGS. 1 and 2, a light distribution and control unit is generally indicated by reference numeral 10. Light distribution and control unit 10 includes a housing 12, a control circuit 14, an LED array 16, a heat sink 18, and fiber optic strands 20. The light distribution and control unit 10 may be mounted in the trunk of a limousine 22 or other vehicle, for example. Fiber optic strands 20 may be embedded in the headliner of the vehicle 22 to provide accent lighting or may provide lighting for a bar or in cabinets mounted in the vehicle, for example. Reference to a vehicle 22 is for illustrative purposes only and not as a limitation. Those skilled in the art will recognize other applications for the present invention such as decorative or accent lighting in hot tubs, for example.

The light emitted from LED light array 16 may be focused by a lens 24 to inject the light into the ends of the fiber optic strands 20. A reflector (not shown) may also be used to direct the light into the optic fiber strands 20. Additionally, a transparent stop 26 may be used to space the ends of the fiber optic strands 20 away from the lens 24 or LED array 16 to protect them from the heat generated by the LED array 16.

Housing 12 may be metal or plastic. Heat sink 18 may be a block of aluminum sized to dissipate the heat created by the LED array 16. LED array 16 is attached to the heat sink 18 with conductive epoxy or metal fasteners with a thermal grease in the joint to ensure efficient and adequate heat transfer.

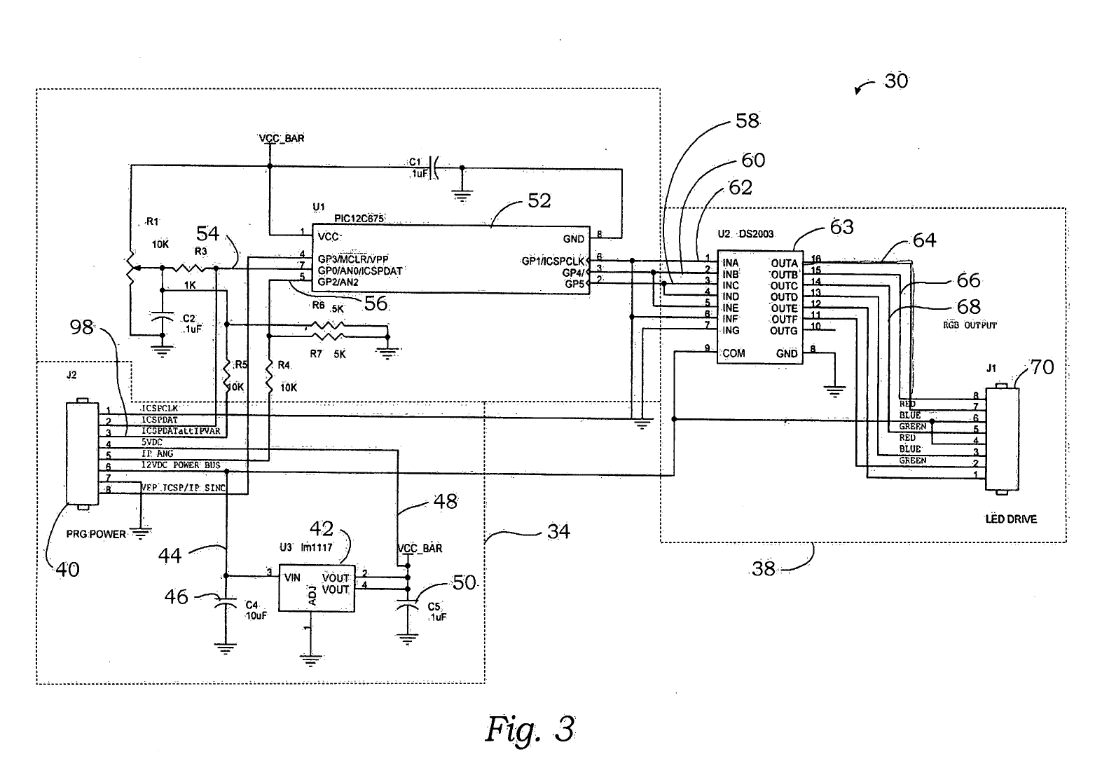

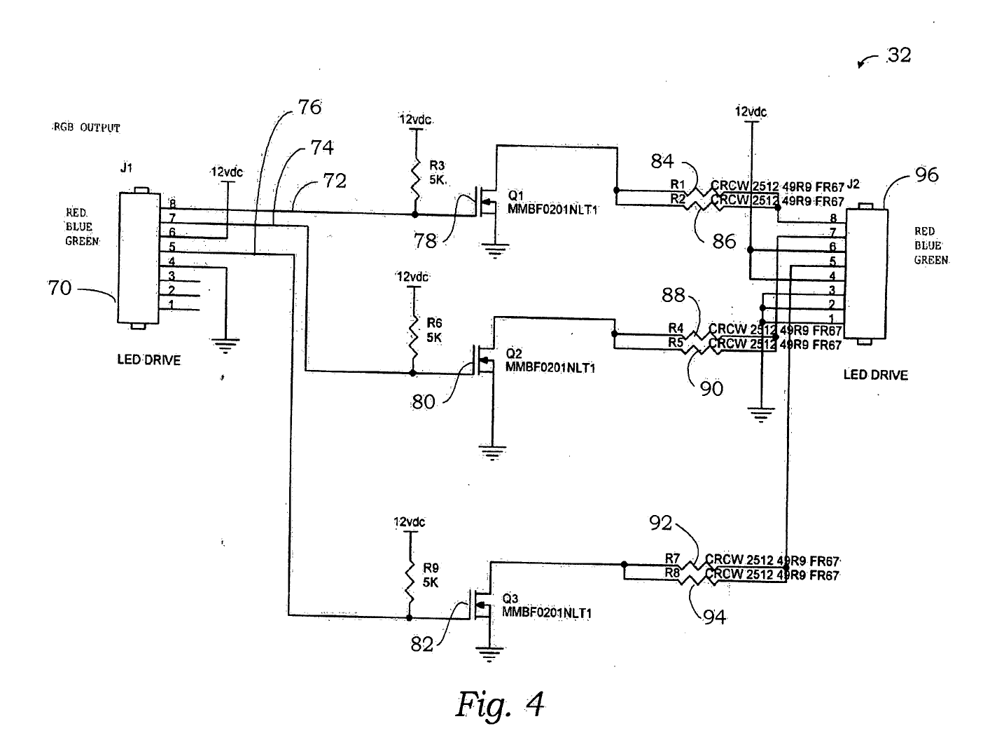

Referring to FIGS. 3 and 4, the control circuit 14 is divided into a power and controller circuit 30 and a current sourcing circuit 32. Power and controller circuit 30 includes a power supply circuit 34, a micro-controller circuit 36 and an LED current driver circuit 38.

The power supply circuit 34 provides power to the system. Power supply circuit 34 includes a power connector 40 and a voltage regulator 42. Voltage regulator 42 receives 12-14 VDC power on line 44. Capacitor 46 filters the input to minimize fluctuations in the input voltage to the voltage regulator 42. Voltage regulator 52 provides a five VDC output on line 48 which is filtered by capacitor 50.

Power and input control signals are provided through connector 40 to microcontroller 52. Microcontroller 52 is an eight-bit microcontroller with an A/D converter and EEPROM data memory such as a PIC12F675, available from Microchip, for example. It should be understood by one skilled in the art that any suitable microcontroller may be used.

The microcontroller 52 may be programmed by connecting an in-circuit programmer (not shown) to connector 40 and downloading a compiled set of instructions to the microcontroller 52.

Based on the input voltage on lines 54 and 56 the microcontroller 52 varies the output on lines 58, 60 and 62 to adjust the duty cycle of the LEDs. Resistors R2, R3, R4, R5, R6 and R7 are used to setup a voltage divider for inputs 54 and 56.

The LED current driver circuit 38 includes a darlington amplifier 63 which takes inputs on lines 48, 60 and 62 and outputs a 12 VDC pulse wave modulated signal on lines 64, 66, 68 which correspond to red, green and blue LEDs, respectively.

The current sourcing circuit 32 includes a connector 70 to the LED current driver circuit 38. Inputs on lines 72, 74 and 76 drive MOSfet transistors 78, 80 and 82 which are high current transistors capable of switching the low power signal from the microcontroller 52 to a high current sourcing output. Resistors 84, 86, 88, 90, 92 and 94 set the current to the LED array (not shown) connected to connector 96.

The LED array 16 (See FIG. 2) may be configured with seven cavities, each populated with LEDs. A RGB light engine such as the Lamina BL-2000 RGB, for example, may be used which contains a multiple red, green and blue LED die in each cavity for optimal color uniformity and high luminous intensity. The LED array has independent color control for dynamic or preset display of colors. Through additive color mixing, there is a complete control of the various colors and white light which can be output.

For an input of 0 volts on line 98, microcontroller 52 outputs a varying signal on lines 58, 60 and 62 that causes the LED array 16 to output a light which slowly fades from one color to the next at a predetermined rate. For an input of 6.7 VDC, the LED array outputs a steady white light. For an input of 10 VDC, the LED array fades from one color to the next at a filter rate to provide a twinkling effect. Finally, at an input voltage of 13.5 VDC, the LED array fades quickly from one color to the next at a predetermined rate.

It is to be understood that while certain forms of this invention have been illustrated and described, it is not limited thereto, except in so far as such limitations are included in the following claims and allowable equivalents thereof.

Having thus described the invention, what is claimed as new and desired to be secured by Letters Patent is:

1. A light distribution and control unit for providing accent lighting to a structure comprising:
a light array having a plurality of light emitting diodes,
a controller in electric communication with said light emitting diodes, said controller programmed to activate said light emitting diodes to produce at least two different light patterns, and
a plurality of optical fibers, each of said optical fibers having an emitting end and a receiving end, said emitting ends of said optical fibers secured to predetermined locations on the structure, said receiving ends of said optical fibers bundled together and substantially aligned to present a light input surface,
said light array and light input surface arranged such that light emitted from said light array is directed to said light input surface such that the light is directed into the receiving ends of said optical fibers and such light is directed through said optical fibers and from the emitting ends of said optical fibers.

2. The light distribution and control unit as set forth in claim 1 further comprising a lens arranged between said light array and said light input surface to focus light emitted from said light array on said light input surface.

3. The light distribution and control unit as set forth in claim 1 wherein said light array includes at least two different colored light emitting diodes.

4. The light distribution and control unit as set forth in claim 1 wherein said light array includes a plurality of red, green and blue light emitting diodes.

5. The light distribution and control unit as set forth in claim 1 wherein said different light patterns may be produced in combination.

6. The light distribution and control unit as set forth in claim 1 wherein said structure is the interior of a vehicle.

7. The light distribution and control unit as set forth in claim 6 wherein said vehicle is a limousine.

8. The light distribution and control unit as set forth in claim 1 wherein said structure is the interior of a hot tub.

9. A light distribution and control unit for providing accent lighting for a structure comprising:
a housing,
a light array mounted in said housing and having a plurality of light emitting diodes,
a control circuit in electric communication with said light emitting diodes and having a controller adapted to activate said light emitting diodes to produce at least two different light patterns, said control circuit mounted in said housing, and
a plurality of optical fibers, each of said optical fibers having an emitting end and a receiving end, said emitting ends of said optical fibers secured to predetermined locations on said structure, said receiving ends of said optical fibers bundled together and substantially aligned to present a light input surface, said light input surface mounted in said housing,
said light array and said light input surface arranged such that light emitted from said light array is directed to said light input surface such that light is directed into the receiving ends of said optical fibers and such light is directed through said optical fibers and from the emitting ends of said optical fibers.

10. The light distribution and control unit as set forth in claim 9 further comprising a lens mounted in said housing between said light array, and said light input surface to focus light emitted from said light array on said light input surface.

11. The light distribution and control unit as set forth in claim 9 wherein said controller is programmable.

12. The light distribution and control unit as claimed in claim 9 wherein said light array includes at least two different colored light emitting diodes.

13. The light distribution and control unit as claimed in claim 9 wherein said light array includes a plurality of red, green and blue light emitting diodes.

14. The light distribution and control unit as claimed in claim 9 where said different light patterns may be produced in combination.

15. The light distribution and control unit as claimed in claim 9 wherein said structure is a vehicle.

16. The light distribution and control unit as claimed in claim 15 wherein said vehicle is a limousine.

17. The light distribution and control unit as claimed in claim 9 wherein said structure is the interior of a hot tub.
